(19) United States
(12) Patent Application Publication
(10) Pub. No.: US 2024/0296987 A1
(43) Pub. Date: Sep. 5, 2024

(54) INDUCTOR COMPONENT

(71) Applicant: Murata Manufacturing Co., Ltd., Kyoto (JP)

(72) Inventor: Hiromitsu ITO, Nagaokakyo-shi (JP)

(73) Assignee: Murata Manufacturing Co., Ltd., Kyoto (JP)

(21) Appl. No.: 18/664,430

(22) Filed: May 15, 2024

Related U.S. Application Data
(63) Continuation of application No. PCT/JP2022/036768, filed on Sep. 30, 2022.
(60) Provisional application No. 63/264,284, filed on Nov. 18, 2021.

(51) Int. Cl. H01F 27/28; H01F 17/00; H01F 27/02

(52) U.S. Cl. CPC H01F 27/2828; H01F 17/0013; H01F 27/022; H01F 2017/002; H01F 2017/004

(57) ABSTRACT

An inductor component comprises, a glass substrate including first and second main surfaces opposed to each other, and a coil on the glass substrate. The coil is wound in a helical shape along an axis, and includes first coil conductors arranged along the axis on the first main surface of the glass substrate, second coil conductors arranged along the axis on the second main surface of the glass substrate, first through conductors arranged in a staggered manner along the axis and penetrating the glass substrate from the first main surface toward the second main surface, and second through conductors arranged in a staggered manner along the axis and penetrating the glass substrate from the first main surface toward the second main surface. The second through conductors are arranged along the axis and are on an opposite side from the first through conductors with respect to the axis.

### CROSS-REFERENCE TO RELATED APPLICATIONS

This application claims benefit of priority to International Patent Application No. PCT/JP2022/036768 filed Sep. 30, 2022, and to U.S. Provisional Patent Application No. 63/264,284, filed Nov. 18, 2021, the entire contents of each are incorporated herein by reference.

### BACKGROUND

### Technical Field

The present disclosure relates to an inductor component.

### Background Art

Conventionally, as an inductor component, there is an inductor component described in JP-A-2020-174169. The inductor component includes a substrate including a top surface and a bottom surface, and a coil provided on the substrate. The coil includes a plurality of bottom surface conductors formed on the bottom surface of the substrate, a plurality of top surface conductors formed on the top surface of the substrate, and a plurality of first through conductors and a plurality of second through conductors penetrating through holes formed in the substrate. The bottom surface conductor, the first through conductor, the top surface conductor, and the second through conductor are connected in this order to form one helical shape.

### SUMMARY

Incidentally, in the conventional inductor component, when it is desired to further increase the inductance value, it is necessary to increase the number of turns of the coil, but there is a problem that the size of the substrate is increased.

Therefore, the present disclosure provides an inductor component capable of improving an inductance value while avoiding an increase in size.

An inductor component according to an aspect of the present disclosure includes a glass substrate including a first main surface and a second main surface opposed to each other; and a coil provided on the glass substrate, the coil wound in a helical shape along an axis. The coil includes a plurality of first coil conductors arranged along the axis on the first main surface of the glass substrate, a plurality of second coil conductors arranged along the axis on the second main surface of the glass substrate, a plurality of first through conductors penetrating the glass substrate from the first main surface toward the second main surface, the plurality of first through conductors arranged along the axis, and a plurality of second through conductors penetrating the glass substrate from the first main surface toward the second main surface. The plurality of second through conductors are provided on an opposite side from the first through conductors with respect to the axis, and the plurality of second through conductors are arranged along the axis. Also, one of the first coil conductors, one of the first through conductors, one of the second coil conductors, and one of the second through conductors are connected in this order to constitute at least a part of the helical shape. The plurality of first through conductors are arranged in a staggered manner along the axis, and the plurality of second through conductors are arranged in a staggered manner along the axis. In addition, at least one of lengths of the plurality of first coil conductors and lengths of the plurality of second coil conductors is formed to alternately repeat long and short along the axis.

Here, “the plurality of first through conductors are arranged in a staggered manner” means that when viewed from a direction orthogonal to the first main surface, the central axes of the plurality of first through conductors do not overlap each other in the axial direction, and the plurality of first through conductors are arranged in a zigzag manner (alternately left and right) along the axis. The same applies to the plurality of second through conductors.

According to the above aspect, the plurality of first through conductors are arranged in a staggered manner along the axis, the plurality of second through conductors are arranged in a staggered manner along the axis, and at least one of the lengths of the plurality of first coil conductors and the lengths of the plurality of second coil conductors is formed so as to alternately repeat long and short along the axis. According to this, when it is desired to increase the number of turns of the coil to further increase the inductance value of the inductor component, even if the interval between the two first coil conductors adjacent to each other in the axis direction is narrowed and the interval between the two second coil conductors adjacent to each other in the axis direction is narrowed, contact between the two first through conductors adjacent to each other in the axis direction can be avoided, and contact between the two second through conductors adjacent to each other in the axis direction can be avoided. As described above, the number of turns of the coil can be increased to further increase the inductance value without increasing the size of the glass substrate. Therefore, the inductance value can be improved while avoiding an increase in size of the inductor component.

In addition, when it is desired to further increase the Q value of the inductor component, even if the diameters of the first through conductor and the second through conductor are increased, it is possible to avoid contact between the two first through conductors adjacent to each other in the axis direction, and it is possible to avoid contact between the two second through conductors adjacent to each other in the axis direction. As described above, even if the size of the glass substrate is not increased, by increasing the diameters of the first through conductor and the second through conductor, the Q value can be further increased. Therefore, the Q value can be improved while avoiding an increase in size of the inductor component.

According to the inductor component according to one aspect of the present disclosure, the inductance value can be improved while avoiding an increase in size.

### BRIEF DESCRIPTION OF THE DRAWINGS

FIG. 1 is a perspective view, as viewed from a top surface side, showing a first embodiment of an inductor component;

FIG. 2 is a top view of the inductor component as viewed from the top surface side;

FIG. 3 is a bottom view of the inductor component as viewed from the bottom surface side;

FIG. 4A is a top view of the inductor component when the number of turns of the coil is increased;

FIG. 4B is a top view of the inductor component when the width of the coil is increased;

FIG. 5 is a perspective view, as viewed from a top surface side, showing a second embodiment of an inductor component;

FIG. 6 is a cross-sectional view taken along line VI-VI in FIG. 5;

FIG. 7 is a top view of the coil of the inductor component as viewed from a top surface side;

FIG. 8 is a bottom view, as viewed from the bottom side, of the coil of the inductor component;

FIG. 9 is a top view, as viewed from the top surface side, of the coil of the inductor component when the number of top surface conductors is an odd number;

FIG. 10 is a bottom view, as viewed from the bottom surface side, of the coil of the inductor component when the number of bottom surface conductors is an even number;

FIG. 11 shows a third embodiment of the inductor component and is a bottom view of the coil of the inductor component as viewed from the bottom surface side;

FIG. 12 is a bottom view, as viewed from the bottom surface side, of the coil of the inductor component when the number of bottom surface conductors is an even number;

FIG. 13 is a cross-sectional view showing a fourth embodiment of an inductor component;

FIG. 14 is a top view, as viewed from a top surface side, showing a fifth embodiment of an inductor component;

FIG. 15 is a bottom view of the inductor component as viewed from the bottom surface side;

FIG. 16 shows a sixth embodiment of the inductor component and is a top view of the coil of the inductor component as viewed from the top surface side;

FIG. 17 is a bottom view of the coil of the inductor component as viewed from the bottom surface side; and

FIG. 18 is a cross-sectional view taken along line XVIII-XVIII in FIG. 16.

### DETAILED DESCRIPTION

Hereinafter, an inductor component which is one aspect of the present disclosure will be described in detail with reference to the illustrated embodiments. It should be noted that the drawings partially include schematic drawings, and may not reflect actual dimensions and ratios.

### First Embodiment

### (Configuration)

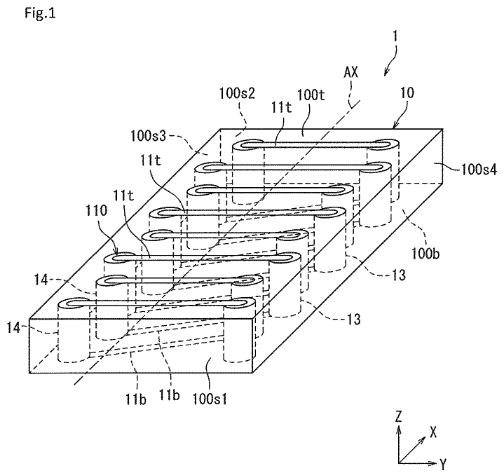

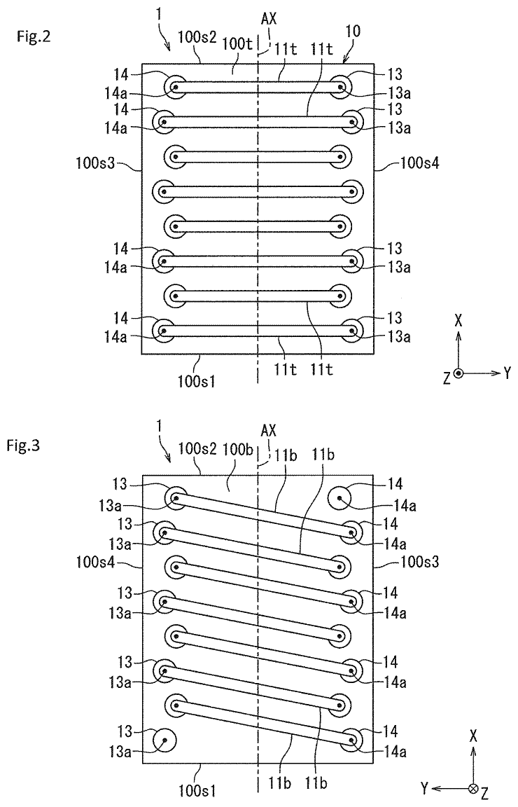

FIG. 1 is a perspective view, as viewed from a top surface side, showing a first embodiment of an inductor component. FIG. 2 is a top view of the inductor component as viewed from the top surface side. FIG. 3 is a bottom view of the inductor component as viewed from the bottom surface side. As shown in FIGS. 1, 2, and 3, the inductor component 1 includes a glass substrate 10 and a coil 110 provided on the glass substrate 10. The inductor component 1 is, for example, a surface mount inductor component used in a high-frequency signal transmission circuit.

The glass substrate 10 is a rectangular parallelepiped having a length, a width, and a height. The glass substrate 10 has a first side surface 100s1 and a second side surface 100s2 on both end sides in the length direction, a third side surface 100s3 and a fourth side surface 100s4 on both end sides in the width direction, and a bottom surface 100b and a top surface 100t on both end sides in the height direction. The first side surface 100s1 and the second side surface 100s2 face each other, the third side surface 100s3 and the fourth side surface 100s4 face each other, and the bottom surface 100b and the top surface 100t face each other. That is, the outer surface of the glass substrate 10 includes the first side surface 100s1 and the second side surface 100s2, the third side surface 100s3 and the fourth side surface 100s4, and the bottom surface 100b and the top surface 100t. The bottom surface 100b is a surface facing the mounting substrate side when the inductor component 1 is mounted on the mounting substrate. The bottom surface 100b corresponds to an example of a first main surface described in the claims, and the top surface 100t corresponds to an example of a second main surface described in the claims.

It should be noted that as shown in the drawings, hereinafter, for convenience of description, a direction being the length direction (longitudinal direction) of the glass substrate 10, the direction from the first side surface 100s1 to the second side surface 100s2 is defined as an X direction. In addition, a direction being the width direction of the glass substrate 10, the direction from the third side surface 100s3 to the fourth side surface 100s4 is defined as a Y direction. In addition, a direction being the height direction of the glass substrate 10, the direction from the bottom surface 100b to the top surface 100t is defined as a Z direction. The X direction, the Y direction, and the Z direction are directions orthogonal to each other, and when arranged in the order of X, Y, and Z, form a left-handed system.

In this specification, the outer surface of the glass substrate 10 does not simply mean a surface facing the outer peripheral side of the glass substrate 10, but is a surface serving as a boundary between the outside and the inside of the glass substrate 10. In addition, the term “above the outer surface (top surface, bottom surface, and side surface) of the glass substrate 10” refers not to an absolute one direction such as a vertically upward direction defined in the gravity direction, but refers to a direction toward the outside between the outside and the inside with the outer surface as a boundary based on the outer surface. Therefore, the term “above the outer surface” is a relative direction determined by the direction of the outer surface. In addition, the term “above” with respect to a certain element includes not only an upper position away from the element, that is, an upper position with interposition of another object on the element or a spaced-apart upper position, but also a position (on) immediately on and in contact with the element.

The glass substrate 10 has an insulating property. The glass substrate 10 is preferably, for example, a glass substrate having photosensitivity represented by Foturan II (registered trademark of Schott AG). By using photosensitive glass for the glass substrate 10, a through via that is thin and has a high aspect ratio can be formed in the glass substrate 10. In particular, the glass substrate 10 preferably contains cerium oxide (ceria: CeO₂), and in this case, the cerium oxide serves as a sensitizer, and processing by photolithography becomes easier.

However, since the glass substrate 10 can be processed by machining such as drilling and sandblasting, dry/wet etching processing using a photoresist/metal mask, laser processing, or the like, the glass substrate 10 may be a glass plate having no photosensitivity. In addition, the glass substrate 10 may be obtained by sintering glass paste or may be formed by a known method such as a float method.

The coil 110 is helically wound around along the axis AX. The axis AX of the coil 110 is disposed parallel to the bottom surface 100b. The coil 110 includes a plurality of bottom surface conductors 11b, a plurality of top surface conductors 11t, a plurality of first through conductors 13, and a plurality of second through conductors 14. The bottom surface conductor 11b corresponds to an example of a “first coil conductor” described in the claims, and the top surface conductor 11t corresponds to an example of a “second coil conductor” described in the claims.

The plurality of bottom surface conductors 11b are disposed above the bottom surface 100b. The plurality of bottom surface conductors 11b are arranged along the axis AX in contact with the bottom surface 100b. The plurality of top surface conductors 11t are disposed above the top surface 100t. The plurality of top surface conductors 11t are arranged along the axis AX in contact with the top surface 100t.

Each of the plurality of first through conductors 13 is provided in the glass substrate 10 and penetrates from the bottom surface 100b toward the top surface 100t. That is, each of the plurality of first through conductors 13 extends from the bottom surface conductor 11b toward the top surface conductor 11t. The plurality of first through conductors 13 are arranged along the axis AX.

Each of the plurality of second through conductors 14 is provided in the glass substrate 10 and penetrates from the bottom surface 100b toward the top surface 100t. That is, each of the plurality of second through conductors 14 extends from the bottom surface conductor 11b toward the top surface conductor 11t. The plurality of second through conductors 14 are arranged along the axis AX. The second through conductor 14 is provided on the opposite side from the first through conductor 13 with respect to the axis AX. The bottom surface conductor 11b, the first through conductor 13, the top surface conductor 11t, and the second through conductor 14 are connected and electrically connected in this order to constitute at least a part of the helical coil 110.

The bottom surface conductor 11b and the top surface conductor 11t are made of a conductor material such as copper, silver, gold, or an alloy thereof. The bottom surface conductor 11b and the top surface conductor 11t may be a metal film formed by plating, vapor deposition, sputtering, or the like, or may be a metal sintered body obtained by applying and sintering a conductor paste. In addition, the materials of the first through conductor 13 and the second through conductor 14 are the same as the materials of the bottom surface conductor 11b and the top surface conductor 11t.

The bottom surface conductor 11b and the top surface conductor 11t are preferably formed by a semi-additive method, whereby a bottom surface conductor 11b and a top surface conductor 11t having low electric resistance, high accuracy, and high aspect can be formed. The first through conductor 13 and the second through conductor 14 can be formed in a through hole formed in advance in the glass substrate 10 using the materials and manufacturing methods exemplified for the bottom surface conductor 11b and the top surface conductor 11t.

When viewed from the direction (Z direction) orthogonal to the bottom surface 100b, the top surface conductor 11t extends in the direction (Y direction) orthogonal to the axis AX. All the top surface conductors 11t are arranged in parallel along the axis AX direction (X direction).

When viewed from the direction (Z direction) orthogonal to the bottom surface 100b, the bottom surface conductor 11b extends in a direction inclined with respect to the direction (Y direction) orthogonal to the axis AX. That is, the bottom surface conductor 11b extends in the Y direction while slightly inclined toward the X direction. All the bottom surface conductors 11b are arranged in parallel along the axis AX direction (X direction).

The first through conductor 13 is disposed on the fourth side surface 100s4 side with respect to the axis AX in the through hole of the glass substrate 10, and the second through conductor 14 is disposed on the third side surface 100s3 side with respect to the axis AX in the through hole of the glass substrate 10. Each of the first through conductor 13 and the second through conductor 14 extends in a direction (Z direction) orthogonal to the bottom surface 100b and the top surface 100t.

When viewed from the direction orthogonal to the top surface 100t, the diameter of the end surface of the first through conductor 13 and the diameter of the end surface of the second through conductor 14 are larger than the width of the top surface conductor 11t. The diameter of the end surface of the first through conductor 13 is the equivalent circle diameter of the end surface of the first through conductor 13, and the diameter of the end surface of the second through conductor 14 is the equivalent circle diameter of the end surface of the second through conductor 14. The width of the top surface conductor 11t is the size in a direction orthogonal to the extending direction of the top surface conductor 11t. Similarly, when viewed from the direction orthogonal to the bottom surface 100b, the diameter of the end surface of the first through conductor 13 and the diameter of the end surface of the second through conductor 14 are larger than the width of the bottom surface conductor 11b.

All the first through conductors 13 are arranged in a staggered manner along the axis AX. Specifically, when viewed from the direction orthogonal to the bottom surface 100b, the central axes 13a of all the first through conductors 13 do not overlap in the axis AX direction, and all the first through conductors 13 are arranged in a zigzag manner (alternately left and right) along the axis AX.

All the second through conductors 14 are arranged in a staggered manner along the axis AX. Specifically, when viewed from the direction orthogonal to the bottom surface 100b, the central axes 14a of all the second through conductors 14 do not overlap in the axis AX direction, and all the second through conductors 14 are arranged in a zigzag manner (alternately left and right) along the axis AX.

The lengths of all the top surface conductors 11t are formed so as to repeat alternating long and short along the axis AX. Specifically, the number of the top surface conductors 11t is an even number of 8. When viewed from a direction orthogonal to the top surface 100t (the bottom surface 100b), a top surface conductor 11t on one outer side (the uppermost side in FIG. 2) in the axis AX direction is a top surface conductor 11t having a short length, and a top surface conductor 11t on the other outer side (the lowermost side in FIG. 2) in the axis AX direction is a top surface conductor 11t having a long length.

On the other hand, all the bottom surface conductors 11b are formed to have the same length. Specifically, the number of the bottom surface conductors 11b is an odd number of seven, and the seven bottom surface conductors 11b have the same length.

According to the above configuration, the plurality of first through conductors 13 are arranged in a staggered manner along the axis AX, the plurality of second through conductors 14 are arranged in a staggered manner along the axis AX, and the lengths of the plurality of top surface conductors 11t are formed to alternately repeat long and short along the axis AX. According to this, when it is desired to increase the number of turns of the coil 110 to further increase the inductance value of the inductor component 1, even if the interval between the two bottom surface conductors 11b adjacent to each other in the axis AX direction is narrowed and the interval between the two top surface conductors 11t adjacent to each other in the axis AX direction is narrowed, contact between the two first through conductors 13 adjacent to each other in the axis AX direction can be avoided, and contact between the two second through conductors 14 adjacent to each other in the axis AX direction can be avoided.

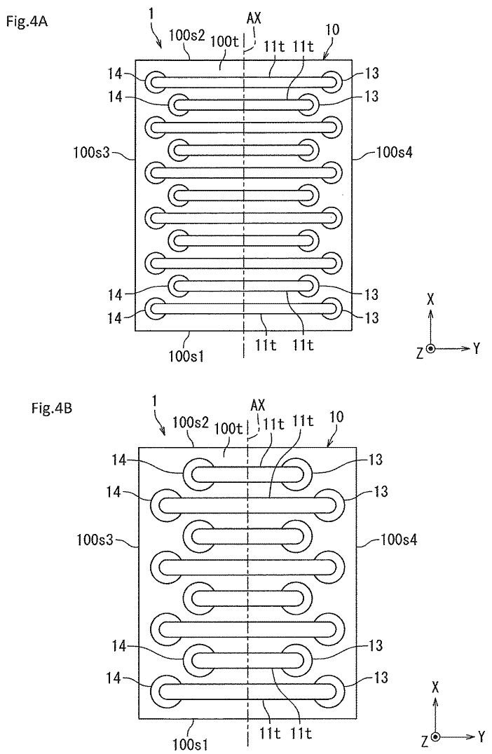

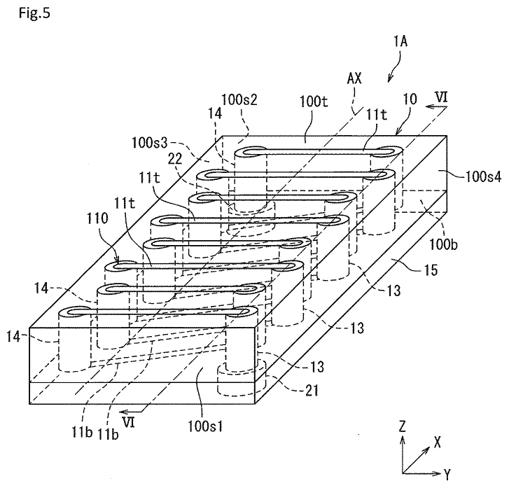

Specifically, as shown in FIG. 4A, even if the number of the top surface conductors 11t is increased and the number of turns of the coil 110 is increased, contact between the two first through conductors 13 adjacent to each other in the axis AX direction can be avoided, and contact between the two second through conductors 14 adjacent to each other in the axis AX direction can be avoided.

As described above, the number of turns of the coil 110 can be increased to further increase the inductance value without increasing the size of the glass substrate 10. Therefore, the inductance value can be improved while avoiding an increase in size of the inductor component 1.

In addition, when it is desired to further increase the Q value of the inductor component 1, even if the diameters of the first through conductor 13 and the second through conductor 14 are increased, it is possible to avoid contact between the two first through conductors 13 adjacent to each other in the axis AX direction, and it is possible to avoid contact between the two second through conductors 14 adjacent to each other in the axis AX direction.

Specifically, as shown in FIG. 4B, even if the diameters of the first through conductor 13 and the second through conductor 14 are increased, it is possible to avoid contact between the two first through conductors 13 adjacent to each other in the axis AX direction, and it is possible to avoid contact between the two second through conductors 14 adjacent to each other in the axis AX direction. In addition, in a range in which the top surface conductor 11t is not in contact with the first through conductor 13 and the second through conductor 14 adjacent to each other in the axis AX direction of the top surface conductor 11t, the width of the top surface conductor 11t can be increased.

As described above, even if the size of the glass substrate 10 is not increased, by increasing the diameters of the first through conductor 13 and the second through conductor 14, the Q value can be further increased. Furthermore, by increasing the widths of the top surface conductor 11t and the bottom surface conductor 11b, the Q value can be further increased. Therefore, the Q value can be improved while avoiding an increase in size of the inductor component 1.

It should be noted that at least one of the lengths of all the bottom surface conductors 11b and the lengths of all the top surface conductors 11t only needs to be formed to alternately repeat long and short along the axis AX. According to this, the inductance value can be improved while avoiding an increase in size of the inductor component 1, and the Q value can be improved while avoiding an increase in size of the inductor component 1.

Preferably, in the two first through conductors 13 adjacent to each other in the axis AX direction, a part of one first through conductor 13 and a part of the other first through conductor 13 overlap each other in the direction orthogonal to the axis AX as viewed from the direction orthogonal to the bottom surface 100b (top surface 100t). In the two second through conductors 14 adjacent to each other in the axis AX direction, a part of one second through conductor 14 and a part of the other second through conductor 14 overlap each other in the direction orthogonal to the axis AX as viewed from the direction orthogonal to the bottom surface 100b (top surface 100t). According to this, the interval between the two bottom surface conductors 11b adjacent to each other in the axis AX direction can be further narrowed, the interval between the two top surface conductors 11t adjacent to each other in the axis AX direction can be further narrowed, and the number of turns of the coil 110 can be further increased.

### (Method for Manufacturing Inductor Component 1)

Next, a method for manufacturing the inductor component 1 will be described with reference to FIGS. 1 to 3.

First, the glass substrate 10 is prepared. The glass substrate 10 is made of, for example, photosensitive glass, and is easy to process through holes and the like. As the glass substrate 10, for example, Foturan II can be used. In general, since the glass substrate 10 contains an oxide such as silicon, lithium, aluminum, or cerium, it is possible to cope with highly accurate photolithography.

Thereafter, through holes for providing the first through conductor 13 and the second through conductor 14 are formed in the glass substrate 10. As a method for forming the through hole, for example, a through hole can be formed by irradiating a region where the through hole is to be formed with ultraviolet rays to crystallize the region, and removing the crystallized portion by etching. It should be noted that the through hole may be formed by laser irradiation.

At this time, the plurality of through holes for providing the first through conductors 13 are arranged in a staggered manner along the X direction, and the plurality of through holes for providing the second through conductors 14 are arranged in a staggered manner along the X direction.

Thereafter, the first through conductor 13 and the second through conductor 14 are formed in the through hole by, for example, electrolytic plating. At this time, the plurality of first through conductors 13 are arranged in a staggered manner along the X direction, and the plurality of second through conductors 14 are arranged in a staggered manner along the X direction.

Thereafter, the top surface conductor 11t electrically connected to the through conductors 13 and 14 is formed on the top surface 100t of the glass substrate 10, and the bottom surface conductor 11b electrically connected to the through conductors 13 and 14 is formed on the bottom surface 100b of the glass substrate 10. The top surface conductor 11t and the bottom surface conductor 11b are formed by, for example, a semi-additive method. At this time, the lengths of all the top surface conductors 11t are formed so as to repeat alternating long and short along the axis AX. All the bottom surface conductors 11b are formed to have the same length. Accordingly, the inductor component 1 can be manufactured.

### Second Embodiment

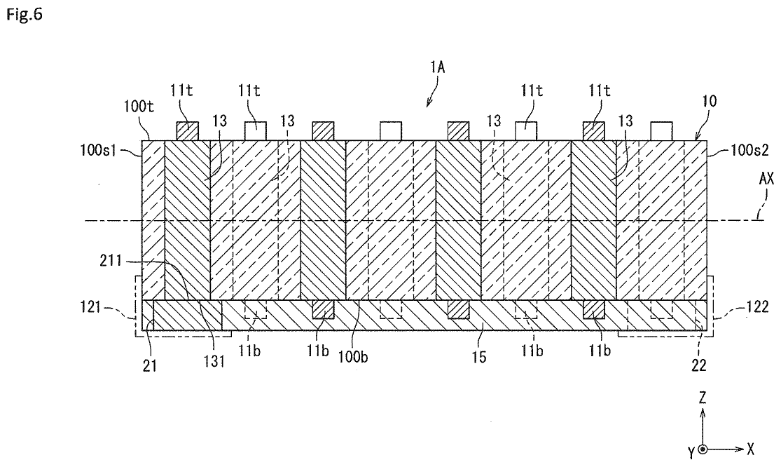

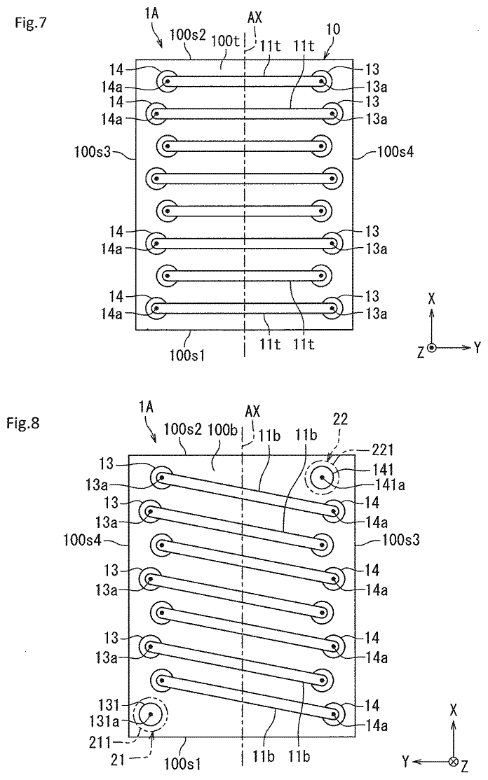

FIG. 5 is a perspective view, as viewed from a top surface side, showing a second embodiment of an inductor component. FIG. 6 is a cross-sectional view taken along line VI-VI in FIG. 5. FIG. 7 is a top view of the coil of the inductor component as viewed from the top surface side, and FIG. 8 is a bottom view of the coil of the inductor component as viewed from the bottom surface side. The second embodiment is different from the first embodiment in that a first protective layer, a first lead conductor, and a second lead conductor are provided. This different configuration will be described below. Other configurations are the same as those of the first embodiment, and the description thereof will be omitted.

As shown in FIGS. 5, 6, 7, and 8, the inductor component 1A according to the second embodiment further includes a first protective layer 15, a first lead conductor 21, and a second lead conductor 22.

The first protective layer 15 is provided on the bottom surface 100b of the glass substrate 10 and covers the bottom surface conductor 11b. The first protective layer 15 is in contact with the bottom surface 100b and the bottom surface conductor 11b. By covering the bottom surface conductor 11b, the first protective layer 15 protects the bottom surface conductor 11b from external force and prevents damage to the bottom surface conductor 11b. In addition, since the first protective layer 15 covers the bottom surface 100b of the glass substrate 10, the glass substrate 10 can be protected. The first protective layer 15 has an insulating property and is made of, for example, a resin such as epoxy or polyimide. It should be noted that a second protective layer covering the top surface conductor 11t may be provided on the top surface 100t of the glass substrate 10.

The first lead conductor 21 is inserted into the through hole of the first protective layer 15 and connected to the endmost first through conductor 13 positioned at the first end portion of the coil 110. The first lead conductor 21 extends in a direction orthogonal to the bottom surface 100b.

The second lead conductor 22 is inserted into the through hole of the first protective layer 15 and connected to the endmost second through conductor 14 positioned at the second end portion of the coil 110. The second lead conductor 22 extends in a direction orthogonal to the bottom surface 100b.

The first lead conductor 21 and the second lead conductor 22 are made of, for example, the same material as the bottom surface conductor 11b. The first lead conductor 21 is connected to, for example, the L-shaped first terminal electrode 121 provided on the first protective layer 15. The second lead conductor 22 is connected to, for example, the L-shaped second terminal electrode 122 provided on the first protective layer 15. The first terminal electrode 121 and the second terminal electrode 122 are indicated by two-dot chain lines in FIG. 6.

The first end surface 211 on the endmost first through conductor 13 side of the first lead conductor 21 is in contact with the first end surface 131 on the first lead conductor 21 side of the endmost first through conductor 13. In FIG. 8, the first end surface 211 of the first lead conductor 21 is indicated by a two-dot chain line. The diameter of the first end surface 211 of the first lead conductor 21 is larger than the diameter of the first end surface 131 of the endmost first through conductor 13. The diameter of the first end surface 211 is the equivalent circle diameter of the first end surface 211, and the diameter of the first end surface 131 is the equivalent circle diameter of the first end surface 131. Here, the glass substrate 10 and the first protective layer 15 have different materials, and in order to enhance the reliability of electrical connection between the glass substrate 10 and the first protective layer 15, the diameter of the first lead conductor 21 provided in the first protective layer 15 is set to be larger than the diameter of the first through conductor 13 provided in the glass substrate 10.

According to the above configuration, when the first lead conductor 21 is provided on the bottom surface 100b of the glass substrate 10 so as to be connected to the endmost first through conductor 13, even if positional displacement of the first lead conductor 21 occurs, since the diameter of the first end surface 211 of the first lead conductor 21 is larger than the diameter of the first end surface 131 of the endmost first through conductor 13, the first lead conductor 21 can be reliably connected to the endmost first through conductor 13.

Similarly, the first end surface 221 on the endmost second through conductor 14 side of the second lead conductor 22 is in contact with the first end surface 141 on the second lead conductor 22 side of the endmost second through conductor 14. In FIG. 8, the first end surface 221 of the second lead conductor 22 is indicated by a two-dot chain line. The diameter of the first end surface 221 of the second lead conductor 22 is larger than the diameter of the first end surface 141 of the endmost second through conductor 14. The diameter of the first end surface 221 is the equivalent circle diameter of the first end surface 221, and the diameter of the first end surface 141 is the equivalent circle diameter of the first end surface 141.

According to the above configuration, when the second lead conductor 22 is provided on the bottom surface 100b of the glass substrate 10 so as to be connected to the endmost second through conductor 14, even if positional displacement of the second lead conductor 22 occurs, since the diameter of the first end surface 221 of the second lead conductor 22 is larger than the diameter of the first end surface 141 of the endmost second through conductor 14, the second lead conductor 22 can be reliably connected to the endmost second through conductor 14.

As shown in FIG. 8, similarly to the first embodiment, all the first through conductors 13 are arranged in a zigzag manner along the axis AX, and all the second through conductors 14 are arranged in a zigzag manner along the axis AX. Accordingly, the first lead conductor 21 can be reliably prevented from coming into contact with the first through conductors 13 adjacent in the axis AX direction to the endmost first through conductor 13, instead of the endmost first through conductor 13 positioned immediately above the first lead conductor 21. In addition, the second lead conductor 22 can be reliably prevented from coming into contact with the second through conductors 14 adjacent in the axis AX direction to the endmost second through conductor 14, instead of the endmost second through conductor 14 positioned immediately above the second lead conductor 22.

In other words, by arranging all the first through conductors 13 in a zigzag manner instead of a linear shape along the axis AX, a distance between the first lead conductor 21 and the first through conductor 13 adjacent in the axis AX direction to the endmost first through conductor 13 can be increased. By arranging all the second through conductors 14 in a zigzag manner instead of a linear shape along the axis AX, a distance between the second lead conductor 22 and the second through conductor 14 adjacent in the axis AX direction to the endmost second through conductor 14 can be increased.

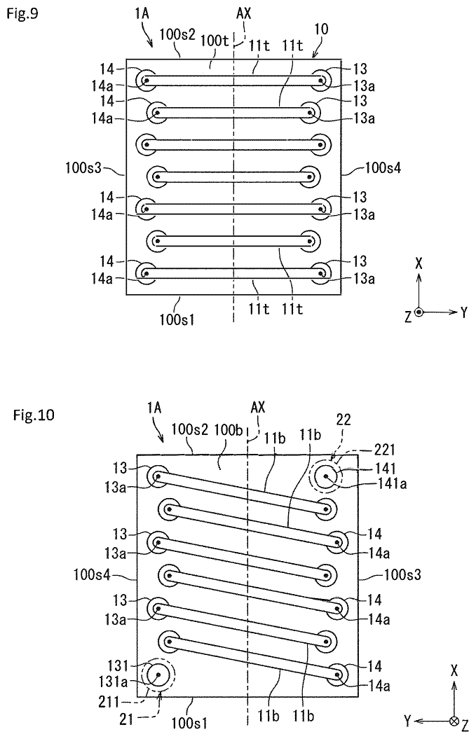

As shown in FIGS. 7 and 8, the number of the top surface conductors 11t is an even number of 8, and the number of the bottom surface conductors 11b is an odd number of 7. On the other hand, as shown in FIGS. 9 and 10, the number of the top surface conductors 11t is an odd number of 7, and the number of the bottom surface conductors 11b is an even number of 6. As described above, depending on whether the number of the top surface conductors 11t in FIG. 7 is an even number or the number of the top surface conductors 11t in FIG. 9 is an odd number, the length of the endmost top surface conductor 11t in the axis AX direction of the coil 110 is different, “long” or “short”. That is, the length of the endmost top surface conductor 11t in FIG. 7 is short, and the length of the endmost top surface conductor 11t in FIG. 9 is long. In any case, the distance between the first lead conductor 21 and the first through conductor 13 adjacent in the axis AX direction to the endmost first through conductor 13 can be increased, and the distance between the second lead conductor 22 and the second through conductor 14 adjacent in the axis AX direction to the endmost second through conductor 14 can be increased.

As shown in FIGS. 7 and 8, when viewed from a direction orthogonal to the bottom surface 100b (top surface 100t), the bottom surface conductor 11b extends in a direction inclined with respect to the direction orthogonal to the axis AX, and the top surface conductor 11t extends in the direction orthogonal to the axis AX.

According to the above configuration, when viewed from the direction orthogonal to the bottom surface 100b (top surface 100t), the first lead conductor 21 can be disposed so that the first lead conductor 21 overlaps the region (dead space) where the bottom surface conductor 11b is not present on the bottom surface 100b of the glass substrate 10. As described above, the first lead conductor 21 can be disposed while avoiding an increase in size of the glass substrate 10. Similarly, when viewed from the direction orthogonal to the bottom surface 100b (top surface 100t), the second lead conductor 22 can be disposed so that the second lead conductor 22 overlaps the region (dead space) where the bottom surface conductor 11b is not present on the bottom surface 100b of the glass substrate 10. As described above, the second lead conductor 22 can be disposed while avoiding an increase in size of the glass substrate 10.

### Third Embodiment

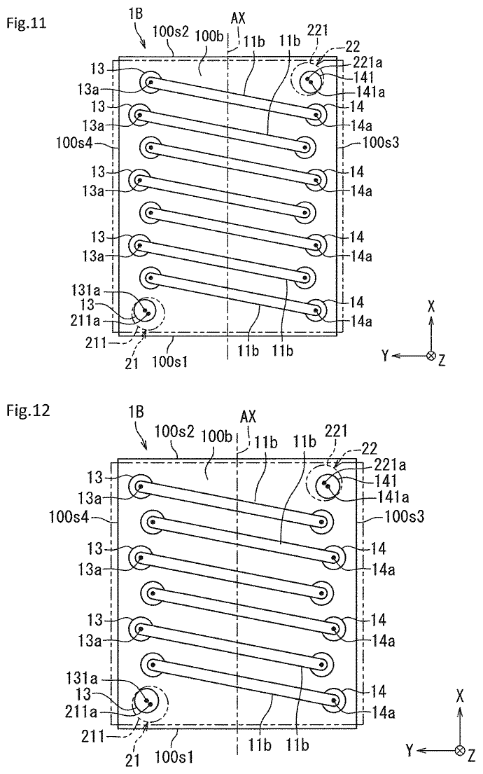

FIG. 11 shows a third embodiment of the inductor component and is a bottom view of the coil of the inductor component as viewed from the bottom surface side. The third embodiment is different from the second embodiment (FIG. 8) in the positions of the first lead conductor and the second lead conductor. This different configuration will be described below. Other configurations are the same as those of the second embodiment, and the description thereof will be omitted.

As shown in FIG. 11, in the inductor component 1B according to the third embodiment, as viewed from the direction orthogonal to the bottom surface 100b, the center 211a of the first end surface 211 of the first lead conductor 21 is separated from the center 131a of the first end surface 131 of the endmost first through conductor 13. The endmost first through conductor 13 is directly connected to the first lead conductor 21. The center 211a of the first end surface 211 is the center of gravity of the first end surface 211. The center 131a of the first end surface 131 is the center of gravity of the first end surface 131 and coincides with the central axis 13a of the first through conductor 13.

Similarly, as viewed from the direction orthogonal to the bottom surface 100b, the center 221a of the first end surface 221 of the second lead conductor 22 is separated from the center 141a of the first end surface 141 of the endmost second through conductor 14. The endmost second through conductor 14 is directly connected to the second lead conductor 22. The center 221a of the first end surface 221 is the center of gravity of the first end surface 221. The center 141a of the first end surface 141 is the center of gravity of the first end surface 141 and coincides with the central axis 14a of the second through conductor 14.

According to the above configuration, since the center 211a of the first end surface 211 and the center 131a of the first end surface 131 are misaligned, the degree of freedom in design is increased as compared with the case where the center 211a of the first end surface 211 and the center 131a of the first end surface 131 coincide with each other as shown in the second embodiment (FIG. 8). Similarly, since the center 221a of the first end surface 221 and the center 141a of the first end surface 141 are misaligned, the degree of freedom in design is increased as compared with the case where the center 221a of the first end surface 221 and the center 141a of the first end surface 141 coincide with each other as shown in the second embodiment (FIG. 8). It should be noted that at least the first lead conductor 21 of the first lead conductor 21 and the second lead conductor 22 only needs to satisfy the above configuration.

As shown in FIG. 11, preferably, when viewed from the direction orthogonal to the bottom surface 100b, the center 211a of the first end surface 211 of the first lead conductor 21 is eccentric toward the axis AX side from the center 131a of the first end surface 131 of the endmost first through conductor 13. According to the above configuration, the first lead conductor 21 having a large diameter can be shifted to the axis AX side, and as viewed from the direction orthogonal to the bottom surface 100b, the width of the glass substrate 10 in the direction orthogonal to the axis AX can be reduced as indicated by a solid line from the two-dot chain line in FIG. 11.

Similarly, preferably, when viewed from the direction orthogonal to the bottom surface 100b, the center 221a of the first end surface 221 of the second lead conductor 22 is eccentric toward the axis AX side from the center 141a of the first end surface 141 of the endmost second through conductor 14. According to the above configuration, the second lead conductor 22 having a large diameter can be shifted to the axis AX side, and as viewed from the direction orthogonal to the bottom surface 100b, the width of the glass substrate 10 in the direction orthogonal to the axis AX can be reduced as indicated by a solid line from the two-dot chain line in FIG. 11.

As shown in FIG. 11, preferably, when viewed from the direction orthogonal to the bottom surface 100b, the center 211a of the first end surface 211 of the first lead conductor 21 is eccentric outward in the axis AX direction from the center 131a of the first end surface 131 of the endmost first through conductor 13. The “outward in the axis AX direction” is the outside of the inductor component 1B in the axis AX direction. According to the above configuration, the first lead conductor 21 having a large diameter can be shifted outward in the axis AX direction, and the first lead conductor 21 can avoid contacting the first through conductor 13 adjacent to the endmost first through conductor 13 in the axis AX direction.

Similarly, preferably, when viewed from the direction orthogonal to the bottom surface 100b, the center 221a of the first end surface 221 of the second lead conductor 22 is eccentric outward in the axis AX direction from the center 141a of the first end surface 141 of the endmost second through conductor 14. The “outward in the axis AX direction” is the outside of the inductor component 1B in the axis AX direction. According to the above configuration, the second lead conductor 22 having a large diameter can be shifted outward in the axis AX direction, and the second lead conductor 22 can avoid contacting the second through conductor 14 adjacent to the endmost second through conductor 14 in the axis AX direction.

In FIG. 11, the number of bottom surface conductors 11b is an odd number of 7. On the other hand, as shown in FIG. 12, the number of bottom surface conductors 11b is an even number of 6. In FIG. 12, the positions of the first lead conductor and the second lead conductor are different from those of the second embodiment (FIG. 10). The positions of the first lead conductor 21 and the second lead conductor 22 shown in FIG. 12 are the same as the positions of the first lead conductor 21 and the second lead conductor 22 shown in FIG. 11. As described above, even if the number of the bottom surface conductors 11b in FIG. 12 is an even number, the same effect as when the number of the bottom surface conductors 11b in FIG. 11 is an odd number is obtained.

### Fourth Embodiment

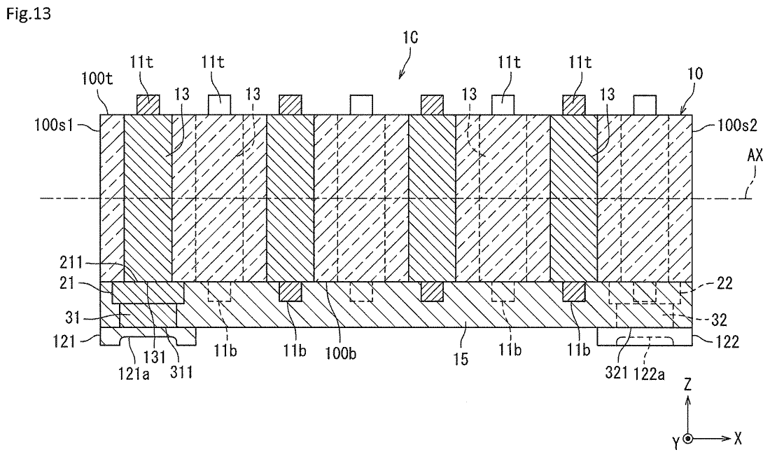

FIG. 13 is a cross-sectional view showing a fourth embodiment of the inductor component. The fourth embodiment is different from the second embodiment (FIG. 6) in that a first via conductor, a second via conductor, a first terminal electrode, and a second terminal electrode are provided. This different configuration will be described below. Other configurations are the same as those of the second embodiment, and the description thereof will be omitted.

As shown in FIG. 13, the inductor component 1C according to the fourth embodiment further includes a first via conductor 31, a second via conductor 32, a first terminal electrode 121, and a second terminal electrode 122.

Each of the first terminal electrode 121 and the second terminal electrode 122 is provided on the opposite side to the bottom surface 100b in the first protective layer 15. The first terminal electrode 121 corresponds to an example of a “first connection conductor” described in the claims, and the second terminal electrode 122 corresponds to an example of a “second connection conductor”. It should be noted that the first connection conductor may be a routing wiring line or the like, instead of the first terminal electrode 121.

The first terminal electrode 121 is connected to the first end portion of the coil 110. The second terminal electrode 122 is connected to the second end portion of the coil 110. The first terminal electrode 121 is provided, on the first protective layer 15, on the first side surface 100s1 side with respect to the center in the X direction of the glass substrate 10. The second terminal electrode 122 is provided, on the first protective layer 15, on the second side surface 100s2 side with respect to the center in the X direction of the glass substrate 10.

The first via conductor 31 is inserted into the through hole of the first protective layer 15 and is positioned between the first lead conductor 21 and the first terminal electrode 121. The first end surface 311 on the first terminal electrode 121 side of the first via conductor 31 is in contact with the first terminal electrode 121. The endmost first through conductor 13 is directly connected to the first lead conductor 21, and the first lead conductor 21 is directly connected to the first via conductor 31. The diameter of the first end surface 311 of the first via conductor 31 is larger than the diameter of the first end surface 131 of the endmost first through conductor 13. The diameter of the first end surface 311 is an equivalent circle diameter of the first end surface 311.

According to the above configuration, since the diameter of the first end surface 311 of the first via conductor 31 is large, the contact area between the first via conductor 31 and the first terminal electrode 121 can be increased, and the connection reliability between the first via conductor 31 and the first terminal electrode 121 can be improved. In addition, by providing the first via conductor 31, the first lead conductor 21 can be formed to have the same degree of thickness as the bottom surface conductor 11b, and the thickness of the first via conductor 31 can be reduced.

Similarly, the second via conductor 32 is inserted into the through hole of the first protective layer 15 and is positioned between the second lead conductor 22 and the second terminal electrode 122. The first end surface 321 on the second terminal electrode 122 side of the second via conductor 32 is in contact with the second terminal electrode 122. The endmost second through conductor 14 is directly connected to the second lead conductor 22, and the second lead conductor 22 is directly connected to the second via conductor 32. The diameter of the first end surface 321 of the second via conductor 32 is larger than the diameter of the first end surface 142 of the endmost second through conductor 14. The diameter of the first end surface 321 is an equivalent circle diameter of the first end surface 321.

According to the above configuration, since the diameter of the first end surface 321 of the second via conductor 32 is large, the contact area between the second via conductor 32 and the second terminal electrode 122 can be increased, and the connection reliability between the second via conductor 32 and the second terminal electrode 122 can be improved. In addition, by providing the second via conductor 32, the second lead conductor 22 can be formed to have the same degree of thickness as the bottom surface conductor 11b, and the thickness of the second via conductor 32 can be reduced.

It should be noted that at least the first via conductor 31 of the first via conductor 31 and the second via conductor 32 only need to satisfy the above configuration.

Preferably, when viewed from a direction orthogonal to the bottom surface 100b, a recessed portion 121a is provided in a region overlapping the first via conductor 31 on the outer surface of the first terminal electrode 121. Accordingly, when the inductor component 1C is mounted on the mounting substrate through solder, the solder enters the recessed portion 121a, and the fixing strength of the first terminal electrode 121 to the mounting substrate can be improved.

Similarly, preferably, when viewed from a direction orthogonal to the bottom surface 100b, a recessed portion 122a is provided in a region overlapping the second via conductor 32 on the outer surface of the second terminal electrode 122. Accordingly, when the inductor component 1C is mounted on the mounting substrate through solder, the solder enters the recessed portion 122a, and the fixing strength of the second terminal electrode 122 to the mounting substrate can be improved.

### Fifth Embodiment

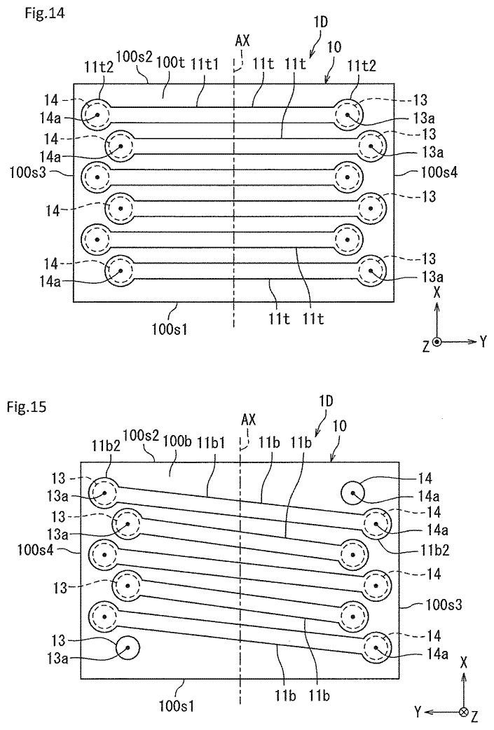

FIG. 14 is a top view showing a fifth embodiment of the inductor component as viewed from a top surface side, and FIG. 15 is a bottom view of the inductor component as viewed from a bottom surface side. The fifth embodiment is different from the first embodiment (FIGS. 2 and 3) in the shapes of the top surface conductor 11t and the bottom surface conductor 11b. This different configuration will be described below. Other configurations are the same as those of the first embodiment, and the description thereof will be omitted.

As shown in FIGS. 14 and 15, in the inductor component 1D of the fifth embodiment, all the top surface conductors 11t are formed to have the same length. Specifically, the number of the top surface conductors 11t is an even number of six, and the six top surface conductors 11t have the same length.

On the other hand, the lengths of all the bottom surface conductors 11b are formed so as to repeat alternating long and short along the axis AX. Specifically, the number of the bottom surface conductors 11b is an odd number of 5. When viewed from a direction orthogonal to the bottom surface 100b, a bottom surface conductor 11b on one outer side (the uppermost side in FIG. 15) in the axis AX direction is a bottom surface conductor 11b having a long length, and a bottom surface conductor 11b on the other outer side (the lowermost side in FIG. 2) in the axis AX direction is a bottom surface conductor 11b having a long length.

According to the above configuration, since the lengths of all the bottom surface conductors 11b are formed so as to alternately repeat long and short along the axis AX, as in the first embodiment, the inductance value can be improved while avoiding an increase in size of the inductor component 1D, and the Q value can be improved while avoiding an increase in size of the inductor component 1D.

As shown in FIG. 14, preferably, the top surface conductor 11t includes an extending portion 11t1 and a pad portion 11t2 provided at each of both ends of the extending portion 11t1. The width of the extending portion 11t1 is smaller than the diameter of the pad portion 11t2. The width of the extending portion 11t1 is a size in a direction orthogonal to the extending direction of the extending portion 11t1 when viewed from the direction orthogonal to the top surface 100t. The diameter of the pad portion 11t2 is an equivalent circle diameter of the pad portion 11t2 when viewed from a direction orthogonal to the top surface 100t.

The diameter of the pad portion 11t2 is larger than the diameter of the end surface of the first through conductor 13 and the diameter of the end surface of the second through conductor 14. Accordingly, when the top surface conductor 11t is provided on the top surface 100t of the glass substrate 10 so as to be connected to the first through conductor 13 and the second through conductor 14, the pad portion 11t2 of the top surface conductor 11t can be reliably connected to the end surface of the first through conductor 13 and the end surface of the second through conductor 14 even if the positional displacement of the top surface conductor 11t occurs.

When viewed from the direction orthogonal to the top surface 100t, the width of the extending portion 11t1 is smaller than the diameter of the end surface of the first through conductor 13 and the diameter of the end surface of the second through conductor 14. Accordingly, it is possible to more reliably prevent the contact between the top surface conductors 11t adjacent to each other in the axis AX direction. It should be noted that when viewed from the direction orthogonal to the top surface 100t, the width of the extending portion 11t1 may be larger than the diameter of the end surface of the first through conductor 13 and the diameter of the end surface of the second through conductor 14, whereby the electrical resistance of the top surface conductor 11t can be reduced.

As shown in FIG. 15, preferably, the bottom surface conductor 11b includes an extending portion 11b1 and a pad portion 11b2 provided at each of both ends of the extending portion 11b1. The width of the extending portion 11b1 is smaller than the diameter of the pad portion 11b2. The width of the extending portion 11b1 is a size in a direction orthogonal to the extending direction of the extending portion 11b1 when viewed from the direction orthogonal to the bottom surface 100b. The diameter of the pad portion 11b2 is an equivalent circle diameter of the pad portion 11b2 when viewed from a direction orthogonal to the bottom surface 100b.

The diameter of the pad portion 11b2 is larger than the diameter of the end surface of the first through conductor 13 and the diameter of the end surface of the second through conductor 14. Accordingly, when the bottom surface conductor 11b is provided on the bottom surface 100b of the glass substrate 10 so as to be connected to the first through conductor 13 and the second through conductor 14, the pad portion 11b2 of the bottom surface conductor 11b can be reliably connected to the end surface of the first through conductor 13 and the end surface of the second through conductor 14 even if the positional displacement of the bottom surface conductor 11b occurs.

When viewed from the direction orthogonal to the bottom surface 100b, the width of the extending portion 11b1 is smaller than the diameter of the end surface of the first through conductor 13 and the diameter of the end surface of the second through conductor 14. Accordingly, it is possible to more reliably prevent the contact between the bottom surface conductors 11b adjacent to each other in the axis AX direction. It should be noted that when viewed from the direction orthogonal to the bottom surface 100b, the width of the extending portion 11b1 may be larger than the diameter of the end surface of the first through conductor 13 and the diameter of the end surface of the second through conductor 14, whereby the electrical resistance of the bottom surface conductor 11b can be reduced.

### Sixth Embodiment

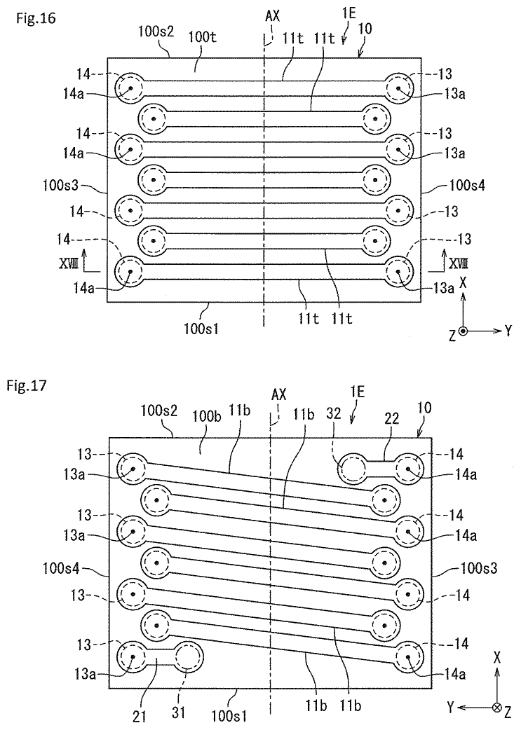

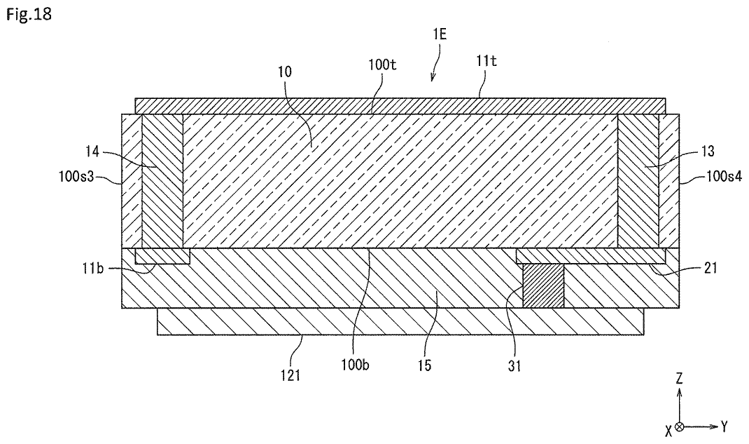

FIG. 16 shows a sixth embodiment of the inductor component and is a top view of the coil of the inductor component as viewed from the top surface side. FIG. 17 is a bottom view of the coil of the inductor component as viewed from the bottom surface side. FIG. 18 is a cross-sectional view taken along line XVIII-XVIII in FIG. 16. The sixth embodiment is different from the fourth embodiment (FIG. 13) in the positions of the first via conductor and the second via conductor. This different configuration will be described below. Other configurations are the same as those of the fourth embodiment, and the description thereof will be omitted.

As shown in FIGS. 16, 17, and 18, in the inductor component 1E of the sixth embodiment, the first lead conductor 21 extends along the Y direction. The first end portion of the first lead conductor 21 is connected to the endmost first through conductor 13, and the second end portion of the first lead conductor 21 is connected to the first via conductor 31. When viewed from the direction orthogonal to the bottom surface 100b, the first via conductor 31 is separated from the endmost first through conductor 13 without overlapping. Accordingly, it is possible to prevent the stress generated by the difference in linear expansion coefficient between the endmost first through conductor 13 and the glass substrate 10 from being concentrated and applied to the first via conductor 31, and it is possible to improve reliability.

Similarly, the second lead conductor 22 extends along the Y direction. The first end portion of the second lead conductor 22 is connected to the endmost second through conductor 14, and the second end portion of the second lead conductor 22 is connected to the second via conductor 32. When viewed from the direction orthogonal to the bottom surface 100b, the second via conductor 32 is separated from the endmost second through conductor 14 without overlapping. Accordingly, it is possible to prevent the stress generated by the difference in linear expansion coefficient between the endmost second through conductor 14 and the glass substrate 10 from being concentrated and applied to the second via conductor 32, and it is possible to improve reliability.

It should be noted that the shapes of the top surface conductor 11t and the bottom surface conductor 11b are the same as the shapes of the top surface conductor 11t and the bottom surface conductor 11b of the fifth embodiment, and the description thereof will be omitted.

It should be noted that the present disclosure is not limited to the above-described embodiments, and can be modified in design in the scope without departing from the gist of the present disclosure. For example, the respective feature points of the first to sixth embodiments may be variously combined. In the first to sixth embodiments, as the inductor component, the surface mount inductor component has been described, but the inductor component may be an inductor component built in the substrate. At this time, the first connection conductor connected to the first via conductor may be a routing wiring line or the like penetrating the substrate instead of the first terminal electrode, and the second connection conductor connected to the second via conductor may be a routing wiring line or the like penetrating the substrate instead of the second terminal electrode.

What is claimed is:

1. An inductor component comprising:
a glass substrate including a first main surface and a second main surface opposed to each other; and
a coil on the glass substrate and coil wound in a helical shape along an axis,
wherein the coil includes:
a plurality of first coil conductors arranged along the axis on the first main surface of the glass substrate,
a plurality of second coil conductors arranged along the axis on the second main surface of the glass substrate,
a plurality of first through conductors penetrating the glass substrate from the first main surface toward the second main surface, the plurality of first through conductors being arranged in a staggered manner along the axis, and
a plurality of second through conductors penetrating the glass substrate from the first main surface toward the second main surface, the plurality of second through conductors being on an opposite side from the first through conductors with respect to the axis, and the plurality of second through conductors being arranged in a staggered manner along the axis,
wherein
one of the first coil conductors, one of the first through conductors, one of the second coil conductors, and one of the second through conductors are connected in this order to configure at least a part of the helical shape, and
wherein at least one of lengths of the plurality of first coil conductors and lengths of the plurality of second coil conductors alternately repeat long and short along the axis.

2. The inductor component according to claim 1, further comprising:
a first protective layer on the first main surface of the glass substrate, the first protective layer covering the first coil conductors, and
a first lead conductor being in a through hole of the first protective layer, the first lead conductor being connected to an endmost first through conductor positioned at a first end portion of the coil,
wherein
a first end surface on an endmost first through conductor side of the first lead conductor is in contact with a first end surface on the first lead conductor side of the endmost first through conductor, and
a diameter of the first end surface of the first lead conductor is larger than a diameter of the first end surface of the endmost first through conductor.

3. The inductor component according to claim 2, wherein
when viewed from a direction orthogonal to the first main surface, a center of the first end surface of the first lead conductor is separated from a center of the first end surface of the endmost first through conductor.

4. The inductor component according to claim 2, wherein
when viewed from a direction orthogonal to the first main surface, a center of the first end surface of the first lead conductor is eccentric toward the axis side from a center of the first end surface of the endmost first through conductor.

5. The inductor component according to claim 2, wherein
when viewed from a direction orthogonal to the first main surface, a center of the first end surface of the first lead conductor is eccentric outward in the axis direction from a center of the first end surface of the endmost first through conductor.

6. The inductor component according to claim 2, further comprising:
a first connection conductor on an opposite side from the first main surface of the first protective layer, and
a first via conductor inserted into the through hole of the first protective layer, the first via conductor being between the first lead conductor and the first connection conductor,
wherein
a first end surface on the first connection conductor side of the first via conductor is in contact with the first connection conductor, and
a diameter of the first end surface of the first via conductor is larger than a diameter of the first end surface of the endmost first through conductor.

7. The inductor component according to claim 1, further comprising:
a first protective layer on the first main surface of the glass substrate, the first protective layer covering the first coil conductors, and
a first lead conductor being in a through hole of the first protective layer, the first lead conductor being connected to an endmost first through conductor positioned at a first end portion of the coil, wherein when viewed from a direction orthogonal to the first main surface,
each of the first coil conductors extends in a direction inclined with respect to a direction orthogonal to the axis, and
each of the second coil conductors extends in a direction orthogonal to the axis.

8. The inductor component according to claim 3, wherein
when viewed from a direction orthogonal to the first main surface, a center of the first end surface of the first lead conductor is eccentric toward the axis side from a center of the first end surface of the endmost first through conductor.

9. The inductor component according to claim 3, wherein
when viewed from a direction orthogonal to the first main surface, a center of the first end surface of the first lead conductor is eccentric outward in the axis direction from a center of the first end surface of the endmost first through conductor.

10. The inductor component according to claim 4, wherein
when viewed from a direction orthogonal to the first main surface, a center of the first end surface of the first lead conductor is eccentric outward in the axis direction from a center of the first end surface of the endmost first through conductor.

11. The inductor component according to claim 8, wherein
when viewed from a direction orthogonal to the first main surface, a center of the first end surface of the first lead conductor is eccentric outward in the axis direction from a center of the first end surface of the endmost first through conductor.

12. The inductor component according to claim 3, further comprising:
a first connection conductor on an opposite side from the first main surface of the first protective layer, and
a first via conductor inserted into the through hole of the first protective layer, the first via conductor being between the first lead conductor and the first connection conductor,
wherein
a first end surface on the first connection conductor side of the first via conductor is in contact with the first connection conductor, and
a diameter of the first end surface of the first via conductor is larger than a diameter of the first end surface of the endmost first through conductor.

13. The inductor component according to claim 4, further comprising:
a first connection conductor on an opposite side from the first main surface of the first protective layer, and
a first via conductor inserted into the through hole of the first protective layer, the first via conductor being between the first lead conductor and the first connection conductor,
wherein
a first end surface on the first connection conductor side of the first via conductor is in contact with the first connection conductor, and
a diameter of the first end surface of the first via conductor is larger than a diameter of the first end surface of the endmost first through conductor.

14. The inductor component according to claim 5, further comprising:
a first connection conductor on an opposite side from the first main surface of the first protective layer, and
a first via conductor inserted into the through hole of the first protective layer, the first via conductor being between the first lead conductor and the first connection conductor,
wherein
a first end surface on the first connection conductor side of the first via conductor is in contact with the first connection conductor, and
a diameter of the first end surface of the first via conductor is larger than a diameter of the first end surface of the endmost first through conductor.

15. The inductor component according to claim 8, further comprising:
a first connection conductor on an opposite side from the first main surface of the first protective layer, and
a first via conductor inserted into the through hole of the first protective layer, the first via conductor being between the first lead conductor and the first connection conductor,
wherein
a first end surface on the first connection conductor side of the first via conductor is in contact with the first connection conductor, and
a diameter of the first end surface of the first via conductor is larger than a diameter of the first end surface of the endmost first through conductor.

16. The inductor component according to claim 2, further comprising:
a first protective layer on the first main surface of the glass substrate, the first protective layer covering the first coil conductors, and
a first lead conductor being in a through hole of the first protective layer, the first lead conductor being connected to an endmost first through conductor positioned at a first end portion of the coil, wherein when viewed from a direction orthogonal to the first main surface,
each of the first coil conductors extends in a direction inclined with respect to a direction orthogonal to the axis, and
each of the second coil conductors extends in a direction orthogonal to the axis.

17. The inductor component according to claim 3, further comprising:
a first protective layer on the first main surface of the glass substrate, the first protective layer covering the first coil conductors, and
a first lead conductor being in a through hole of the first protective layer, the first lead conductor being connected to an endmost first through conductor positioned at a first end portion of the coil, wherein when viewed from a direction orthogonal to the first main surface,
each of the first coil conductors extends in a direction inclined with respect to a direction orthogonal to the axis, and
each of the second coil conductors extends in a direction orthogonal to the axis.

18. The inductor component according to claim 4, further comprising:
a first protective layer on the first main surface of the glass substrate, the first protective layer covering the first coil conductors, and
a first lead conductor being in a through hole of the first protective layer, the first lead conductor being connected to an endmost first through conductor positioned at a first end portion of the coil, wherein when viewed from a direction orthogonal to the first main surface,
each of the first coil conductors extends in a direction inclined with respect to a direction orthogonal to the axis, and
each of the second coil conductors extends in a direction orthogonal to the axis.

19. The inductor component according to claim 5, further comprising:
a first protective layer on the first main surface of the glass substrate, the first protective layer covering the first coil conductors, and
a first lead conductor being in a through hole of the first protective layer, the first lead conductor being connected to an endmost first through conductor positioned at a first end portion of the coil, wherein when viewed from a direction orthogonal to the first main surface,
each of the first coil conductors extends in a direction inclined with respect to a direction orthogonal to the axis, and
each of the second coil conductors extends in a direction orthogonal to the axis.

20. The inductor component according to claim 6, further comprising:
a first protective layer on the first main surface of the glass substrate, the first protective layer covering the first coil conductors, and
a first lead conductor being in a through hole of the first protective layer, the first lead conductor being connected to an endmost first through conductor positioned at a first end portion of the coil, wherein when viewed from a direction orthogonal to the first main surface,
each of the first coil conductors extends in a direction inclined with respect to a direction orthogonal to the axis, and
each of the second coil conductors extends in a direction orthogonal to the axis.
